(19) United States
(12) Patent Application Publication
(10) Pub. No.: US 2021/0184183 A1
(43) Pub. Date: Jun. 17, 2021

(54) MANUFACTURING METHOD OF GRAPHENE OXIDE FILM, ORGANIC LIGHT-EMITTING DIODE, AND MANUFACTURING METHOD THEREOF

(71) Applicant: WUHAN CHINA STAR OPTOELECTRONICS SEMICONDUCTOR DISPLAY TECHNOLOGY CO,, LTD., Wuhan (CN)

(72) Inventor: Yamin WANG, Wuhan (CN)

(73) Assignee: WUHAN CHINA STAR OPTOELECTRONICS SEMICONDUCTOR DISPLAY TECHNOLOGY CO,, LTD., Wuhan (CN)

(21) Appl. No.: 16/649,680

(22) PCT Filed: Dec. 13, 2019
(86) PCT No.: PCT/CN2019/125080

§ 371 Date: Mar. 23, 2020

(51) Int. Cl. H01L 51/56; H01L 51/50; H01L 51/00; B05D 1/00; B05D 3/00; C23C 14/35; C23C 14/24; C23C 14/08; C23C 14/18

(52) U.S. Cl. CPC H01L 51/56; H01L 51/5088; H01L 51/0003; H01L 51/0008; B05D 1/005; H01L 51/0081; C23C 14/35; C23C 14/24; C23C 14/086; C23C 14/18; H01L 51/0059; B05D 3/007

(57) ABSTRACT

A manufacturing method of a graphene oxide film, an organic light-emitting diode (OLED) and a manufacturing method thereof are provided. The OLED includes a substrate, an anode, a hole injection layer, a hole transport layer, a light-emitting layer, an electron transport layer, an electron injection layer, and a cathode stacked in sequence. The hole injection layer is a graphene oxide layer having a concentration ranging from 0.3 to 1 mg/ml. The hole transport layer is any one of N,N′-diphenyl-N,N′-bis(3-tolyl)-1,1′-biphenyl-4,4′-diamine, 1,4-bis(diphenylamino) biphenyl, or N,N′-diphenyl-N,N′-bis(1-naphthyl)-1,1′-biphenyl-4,4′-diamine.

### FIELD OF INVENTION

The present disclosure relates to the field of display technologies, and more particularly, to a manufacturing method of a graphene oxide film, an organic light-emitting diode (OLED), and a manufacturing method thereof.

### BACKGROUND OF INVENTION

Organic light-emitting diodes (organic light emission diodes, OLEDs) possess advantages of high brightness, a wide range of materials selection, low driving voltages, fully-cured active light emission, etc. Moreover, OLEDs possess advantages of high definition, wide viewing angles, and fast response time. OLEDs are thus display technologies and light sources with great potential. Luminous performance of OLEDs is mainly associate with energy-level matching between functional layers. However, traditional OLEDs have poor luminous efficiency and stability. Affinity between each functional layer is weak, such that the energy level matching between the functional layers is poor. Therefore, the luminous efficiency of the OLEDs is directly affected.

In summary, in existing OLEDs and manufacturing methods thereof, the energy level matching between the functional layers is poor because of the weak affinity between each functional layer. Therefore, the luminous efficiency of the OLEDs is directly affected.

### Technical Problems

In existing OLEDs and manufacturing methods thereof, the energy level matching between the functional layers is poor because of the weak affinity between each functional layer. Therefore, the luminous efficiency of the OLEDs is directly affected.

### SUMMARY OF INVENTION

### Technical Solutions

In a first aspect, an embodiment of the present disclosure provides a manufacturing method of a graphene oxide film, comprising:

a step S10 of providing a graphene oxide aqueous solution in an initial concentration which is a specific concentration, and dispersing the initial concentration to a first concentration by an ultraviolet reduction process to prepare a first graphene oxide solution;

a step S20 of putting the first graphene oxide solution into an ultrasonic cleaning apparatus and subjecting the first graphene oxide solution to a shaking water bath in the ultrasonic cleaning apparatus at a first temperature; and

a step S30 of coating the first graphene oxide solution, after being subjected to the shaking water bath, to form a graphene oxide film by a spin-coating process.

In the manufacturing method of the graphene oxide film, in the step S10, the first concentration is 0.06-0.2 times as much as the initial concentration.

In the manufacturing method of the graphene oxide film, in the step S20, the first temperature ranges from 20 to 40° C. and duration of subjecting the first graphene oxide solution to the shaking water bath ranges from 2 to 6 hours.

In the second aspect, an embodiment of the present disclosure further provides an organic light-emitting diode (OLED), comprising: a substrate, an anode, a hole injection layer, a hole transport layer, a light-emitting layer, an electron transport layer, an electron injection layer, and a cathode stacked in sequence, wherein the hole injection layer is a graphene oxide layer, and the hole transport layer is any one of N,N′-diphenyl-N,N′-bis(3-tolyl)-1,1′-biphenyl-4,4′-diamine, 1,4-bis(diphenylamino) biphenyl, or N,N′-diphenyl-N,N′-bis(1-naphthyl)-1,1′-biphenyl-4,4′-diamine.

In the OLED, a concentration of a graphene oxide solution used in the graphene oxide layer ranges from 0.3 to 1 mg/ml.

In the third aspect, an embodiment of the present disclosure further provides a manufacturing method of an organic light-emitting diode (OLED), comprising:

a step S10 of forming an anode on a cleaned substrate by a magnetron sputtering process to obtain an anode substrate;

a step S20 of adjusting a concentration of a graphene oxide solution by an ultraviolet reduction process, and then coating the graphene oxide solution on the anode substrate by a spin coating process, and performing a drying treatment to form a hole injection layer; and

a step S30 of depositing a hole transport layer, a light-emitting layer, an electron transport layer, an electron injection layer, and a cathode on the hole injection layer in sequence by evaporation processes.

In the manufacturing method of the OLED, the S20 further comprises:

a step S201 of providing a graphene oxide aqueous solution in an initial concentration which is a specific concentration and adjusting the concentration of the graphene oxide solution by the ultraviolet reduction process to prepare a first graphene oxide solution; and

a step S202 of subjecting the first graphene oxide solution to a shaking water bath via an ultrasonic cleaning instrument for 2-6 hours, wherein an ultrasonic process is controlled at 20-40° C., and then coating the first graphene oxide solution on the anode substrate, and performing the drying treatment to form the hole injection layer.

In the manufacturing method of the OLED, in the step S201, the first concentration is 0.06 to 0.2 times as much as the initial concentration.

In the manufacturing method of the OLED, in the step S30, an evaporation rate of the light-emitting layer is between 1-4 Å/s, an evaporation rate of the electron injection layer is between 0.1-0.3 Å/s, and an evaporation rate of the cathode is between 1-5 Å/s.

In the manufacturing method of the OLED, in the step S30, material of the light-emitting layer is tris(8-hydroxyquinoline) aluminum, material of the electron injection layer is LiF, and material of the cathode is Al.

### Beneficial Effects

Compared with the prior art, the manufacturing method of the graphene oxide film, the OLED, and the manufacturing method thereof provided by the present disclosure employ different concentrations of the graphene oxide solution as a hole injection layers and employ specific types of hole transport layers, which are beneficial to the injection and transport of holes and further increase luminous efficiency of OLED.

### DESCRIPTION OF DRAWINGS

FIG. 1 is a flowchart of a manufacturing method of a graphene oxide film according to an embodiment of the present disclosure.

FIG. 2 is a schematic structural diagram of an OLED according to an embodiment of the present disclosure.

FIG. 3 is a flowchart of a manufacturing method of an OLED according to an embodiment of the present disclosure.

FIGS. 3A-3B are schematic diagrams of the manufacturing method of the OLED shown in FIG. 3.

FIG. 4 is an electroluminescence spectrum diagram of an OLED using TPD as a hole transport layer and using three different concentrations of graphene oxide as a hole injection layer.

FIG. 5 is a voltage-luminance curve diagram of an OLED using TPD as a hole transport layer and using three different concentrations of graphene oxide as a hole injection layer.

FIG. 6 is an electroluminescence spectrum diagram of an OLED using 0.5 mg/mL of graphene oxide as a hole injection layer and using three different materials as a hole transport layer.

### DETAILED DESCRIPTION OF PREFERRED EMBODIMENTS

The present disclosure provides a manufacturing method of a graphene oxide film, an OLED, and a manufacturing method thereof. In order to make purposes, technical solutions, and effects of the application to be clearer and more specific, the present disclosure is further described with reference to the drawings and examples. It is to be understood that the specific embodiments described herein are only used to explain the present disclosure, and are not intended to limit the present disclosure.

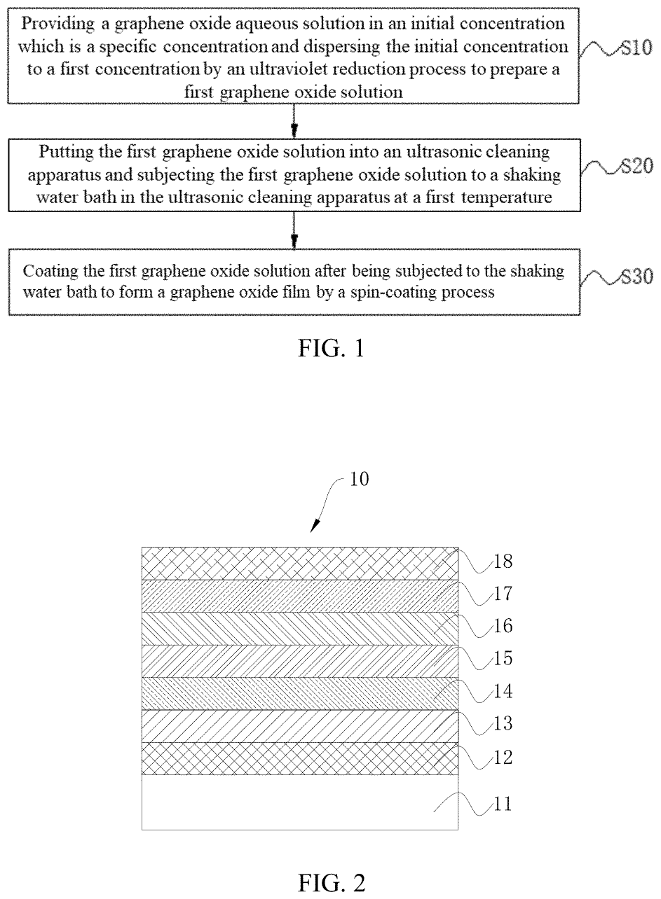

As shown in FIG. 1. FIG. 1 is a flowchart of a manufacturing method of a graphene oxide film according to an embodiment of the present disclosure. The manufacturing method includes the following:

a step S10 of providing a graphene oxide aqueous solution in an initial concentration which is a specific concentration and dispersing the initial concentration to a first concentration by an ultraviolet reduction process to prepare a first graphene oxide solution.

Specifically, the step S10 further includes the following:

First, a specific concentration of graphene oxide aqueous solution is obtained from commercial sources. The specific concentration may be 5 mg/ml. Then, the initial concentration of the graphene oxide solution is dispersed to a first concentration by an ultraviolet reduction process to prepare a first graphene oxide solution. The concentration of the first concentration is 0.06 to 0.2 times as much as the initial concentration. Preferably, when the initial concentration is set to 5 mg/ml, the first concentration ranges from 0.3 mg/ml to 1 mg/ml. Preferably, the initial concentration of the graphene oxide solution is dispersed into a graphene oxide solution A having a solution concentration of 0.3 mg/ml, a graphene oxide solution B having a solution concentration of 0.5 mg/ml, and an Graphene solution C having a solution concentration of 1 mg/ml.

a step S20 of putting the first graphene oxide solution into an ultrasonic cleaning apparatus and subjecting the first graphene oxide solution to a shaking water bath in the ultrasonic cleaning apparatus at a first temperature.

Specifically, the step S20 further includes the following:

Afterwards, the first graphene oxide solution is put into an ultrasonic cleaning apparatus and is subjected to the shaking water bath at the first temperature. The first temperature ranges from 20 to 40° C. and duration of subjecting the first graphene oxide solution to the shaking water bath ranges from 2 to 6 hours. Preferably, the first graphene oxide solution includes the graphene oxide solution A, the graphene oxide solution B, and the graphene oxide solution C.

A step S30 of coating the first graphene oxide solution after being subjected to the shaking bath to form a graphene oxide film by a spin-coating process.

Specifically, the step S30 further includes the following:

Finally, the first graphene oxide solution after being subject to the shaking bath is coated to form a graphene oxide film by the spin-coating process. Preferably, the graphene oxide film includes a film prepared from the graphene oxide solution A, a film prepared from the graphene oxide solution B, and a film prepared from the graphene oxide solution C.

As shown in FIG. 2. FIG. 2 is a schematic structural diagram of an OLED according to an embodiment of the present disclosure. The OLED 10 includes a substrate 11, an anode 12, a hole injection layer 13, a hole transport layer 14, a light-emitting layer 15, an electron transport layer 16, an electron injection layer 17, and a cathode 18 stacked in sequence. The hole injection layer 13 is a graphene oxide layer. The hole transport layer 14 is one of N,N′-diphenyl-N,N′-bis(3-tolyl)-1,1′-biphenyl-4,4′-diamine, 1,4-bis(diphenylamino) biphenyl, or N,N′-diphenyl-N,N′-bis(1-naphthyl)-1,1′-biphenyl-4,4′-diamine.

Preferably, the substrate 11 is a glass substrate.

Specifically, the anode 12 is preferably indium tin oxide (ITO).

Specifically, when the graphene oxide of the graphene oxide layer is in an oxidized state, the sp² hybrid conjugation of graphene itself will be destroyed which results in the lack of freely moving 7E electrons. The graphene oxide is in an insulated state and have a wide energy gap, about 3.5 eV or more. When the graphene oxide of the graphene oxide layer is in a reduced state, freely moving 7E electrons can be generated in a conjugated region, which is in a conductive state. The use of graphene oxide as a hole injection layer effectively increases an injection rate of holes, thereby increasing a light emission rate of the OLED.

Specifically, the concentration of the graphene oxide solution used for the graphene oxide layer ranges from 0.3 mg/ml to 1 mg/ml. Preferably, the concentration of the graphene oxide solution used for the graphene oxide layer is 0.3 mg/ml, or 0.5 mg/ml, or 1 mg/ml.

Specifically, material of the light-emitting layer 15 is preferably tris(8-hydroxyquinoline) aluminum (Alq₃).

Specifically, material of the electron transport layer 16 is preferably tris(8-hydroxyquinoline) aluminum (Alq₃).

Specifically, material of the electron injection layer is preferably LiF.

Specifically, material of the cathode is preferably Al.

The OLEDs provided in the embodiments of the present disclosure employ different concentrations of graphene oxide films as hole injection layers and employ specific hole transport layers, which greatly increases conductivity of the OLEDs and further increases light-emitting efficiency of the OLED.

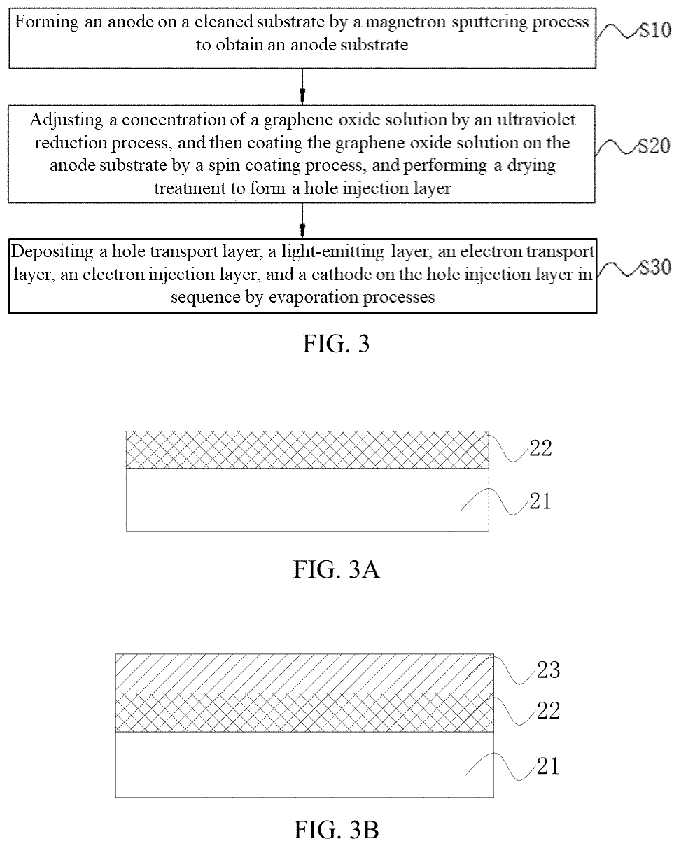

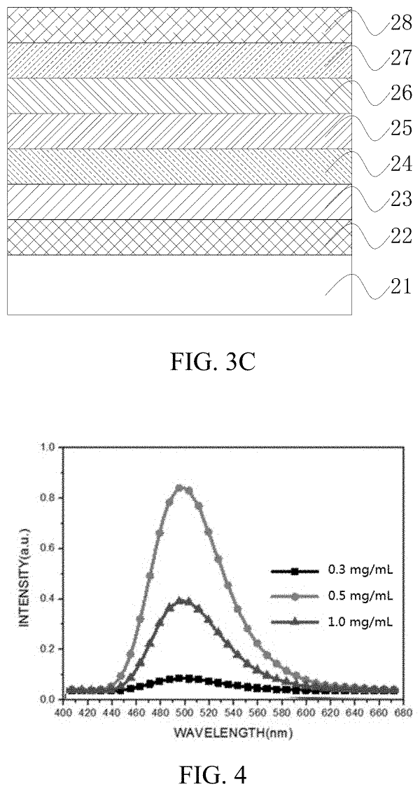

As shown in FIG. 3. FIG. 3 is a flowchart of a manufacturing method of an OLED according to an embodiment of the present disclosure. The manufacturing method is as follows:

a step S10 of forming an anode 22 on a cleaned substrate by a magnetron sputtering process to obtain an anode substrate 21.

Specifically, the step S10 further includes the following:

First, a substrate 21 is provided. The substrate 21 is preferably a glass substrate. After being rinsed with distilled water and ethanol, the substrate 21 is immersed in isopropyl alcohol for one night, and is then dried for use. Then, an anode 22 is formed on the substrate 21 by the magnetron sputtering process to obtain an anode substrate. Material of the anode 22 is conductive ITO glass and has a sputtering rate of 0.2 nm/s. Afterwards, the anode substrate is rinsed with deionized water, then the anode substrate is rinsed with warm water for 30-50 min, dried, and is finally washed in an ion cleaner for 6-15 min. The use of plasma treatment here is to increase work function of the ITO surface to 4-8 eV or more, and increase the interface contact between the anode substrate and the subsequent organic functional layer, as shown in FIG. 3A.

A step S20 of adjusting a concentration of a graphene oxide solution by an ultraviolet reduction process, and then coating the graphene oxide solution on the anode substrate by a spin coating process, and performing a drying treatment to form a hole injection layer 23.

Specifically, the step S20 further includes the following:

First, a specific concentration of graphene oxide aqueous solution is obtained from commercial sources. The specific concentration may be 5 mg/ml. Then, the initial concentration of the graphene oxide solution is dispersed to a first concentration by an ultraviolet reduction process to prepare a first graphene oxide solution. The concentration of the first concentration is 0.06 to 0.2 times as much as the initial concentration. Preferably, when the initial concentration is set to 5 mg/ml, the first concentration ranges from 0.3 mg/ml to 1 mg/ml. Preferably, the initial concentration of the graphene oxide solution is dispersed into a graphene oxide solution A having a solution concentration of 0.3 mg/ml, a graphene oxide solution B having a solution concentration of 0.5 mg/ml, and a graphene oxide solution C having a solution concentration of 1 mg/ml. Afterwards, the first graphene oxide solution is subjected to a shaking water bath via an ultrasonic cleaning instrument for 2-6 hours. The ultrasonic process is controlled at 20-40° C., and then different concentrations of the graphene oxide solutions (equal amounts) are coated on three of the anode substrates via the spin coating process. Three batches of the sample were prepared and dried to obtain the hole injection layer 23, as shown in the FIG. 3B.

A step S30 of depositing a hole transport layer 24, a light-emitting layer 25, an electron transport layer 26, an electron injection layer 27, and a cathode 28 on the hole injection layer 23 in sequence by evaporation processes.

Specifically, the step S30 further includes the following:

First, the anode substrate that is spin-coated with graphene oxide is fixed on a mask plate, transferred to a vacuum evaporation chamber, and vacuumed using a molecular pump. Until the degree of vacuum is lower than 4.0×10⁻⁴ Pa to 6.5×10⁻⁴ Pa, a hole transport layer 24 is deposited on the hole injection layer 23. The hole transport layer 24 is N,N′-diphenyl-N,N′-bis(3-tolyl)-1,1′-biphenyl-4,4′-diamine (TPD), 1,4-bis(diphenylamino) biphenyl (DDB), and N,N′-diphenyl-N,N′-bis(1-naphthyl)-1,1′-biphenyl-4,4′-diamine (NPB). Thereafter, a light-emitting layer 25, an electron transporting layer 26, an electron injection layer 27, and a cathode 28 are deposited on the hole transporting layer 24 in sequence. Finally, OLEDs with different concentrations of graphene oxide and OLEDs that correspond to different hole transport layers are obtained, as shown in FIG. 3C.

An evaporation rate of the light-emitting layer 25 is between 1 to 4 Å/s. Material of the light-emitting layer 25 is preferably tris(8-hydroxyquinoline) aluminum (Alq₃). Material of the electron transport layer 26 is preferably tris(8-hydroxyquinoline) aluminum (Alq₃). An evaporation rate of the electron injection layer 27 is between 0.1 to 0.3 Å/s. Material of the electron injection layer is preferably LiF. An evaporation rate of the cathode 28 is between 1 to 5 Å/s. Material of the cathode 28 is preferably Al.

Preferably, the manufacturing method of an OLED provided in the embodiments of the present disclosure obtains OLEDs of 9 different embodiments. Details are described as follows:

The OLED A₁ includes a hole injection layer that is prepared from a 0.3 mg/ml of the graphene oxide solution and a hole transporting layer that is prepared from N,N′-diphenyl-N,N′-bis(3-tolyl)-1,1′-biphenyl-4,4′-diamine (TPD). The OLED A₂ includes a hole injection layer that is prepared from a 0.5 mg/ml of the graphene oxide solution and a hole-transporting layer that is prepared from N,N′-diphenyl-N,N′-bis(3-tolyl)-1,1′-biphenyl-4,4′-diamine. The OLED A₃ includes a hole injection layer that is prepared from 1 mg/ml of the graphene oxide solution and a hole transport layer that is prepared from N,N′-diphenyl-N,N′-bis(3-tolyl)-1,1′-biphenyl-4,4′-diamine (TPD).

The OLED B₁ includes a hole injection layer that is prepared from a 0.3 mg/ml of the graphene oxide solution and a hole transport layer that is prepared from 1,4-bis(diphenylamino) biphenyl (DDB). The OLED B₂ includes a hole injection layer that is prepared from a 0.5 mg/ml of the graphene oxide solution and a hole transport layer that is prepared from 1,4-bis(diphenylamino) biphenyl (DDB). The OLED B₃ includes a hole injection layer prepared from 1 mg/ml of the graphene oxide solution and a hole transport layer that is prepared from 1,4-bis(diphenylamino) biphenyl (DDB).

The OLED C₁ includes a hole injection layer that is prepared from 0.3 mg/ml of the graphene oxide solution and a hole transport layer that is prepared from N,N′-diphenyl-N,N′-bis(3-tolyl)-1,1′-biphenyl-4,4′-diamine (NPB). The OLED C₂ includes a hole injection layer that is prepared from 0.5 mg/ml of the graphene oxide solution and a hole transport layer that is prepared from N,N′-diphenyl-N,N′-bis(3-tolyl)-1,1′-biphenyl-4,4′-diamine (NPB). The OLED C₃ includes a hole injection layer that is prepared from 1 mg/ml of the graphene oxide solution and a hole transport layer that is prepared from N,N′-diphenyl-N,N′-bis(3-tolyl)-1,1′-biphenyl-4,4′-diamine.

As shown in FIG. 4. FIG. 4 is an electroluminescence spectrum diagram of an OLED using TPD as a hole transport layer and using three different concentrations of graphene oxide as a hole injection layer. The abscissa is wavelength (in nm) and the ordinate is intensity (in absorbance unit, abbreviated as au). It can be seen from FIG. 4 that the light-emitting layer of the OLED is Alq₃. Positions of peaks on the electroluminescence spectrum of the OLED having different concentrations of graphene oxide as the hole injection layer are all around 502 nm. Therefore, the concentration of the graphene oxide solution does not have much influence on the electroluminescence peak of Alq₃.

As shown in FIG. 5. FIG. 5 is a voltage-luminance curve diagram of an OLED using TPD as a hole transport layer and using three different concentrations of graphene oxide as a hole injection layer. The abscissa is voltage (in V) and the ordinate is brightness (luminance, in cd/m²). It can be seen from FIG. 5 that the light-emitting layer of this OLED is Alq₃. In the case that other functional layers are unchanged, the hole injection ability of OLEDs having different concentrations of graphene oxide as the hole injection layer is different. The voltage is less than or equal to 7V. As the concentration of the graphene oxide solution increases, the luminous ability of the graphene oxide solution increases. When the voltage is greater than about 7V, the hole injection ability of the OLED having a 0.5 mg/ml of the graphene oxide solution as a hole injection layer is greater than the hole injection ability of the OLED having more than 1 mg/ml of the graphene oxide solution. When the graphene oxide solution having a concentration of 5 mg/ml is used as a hole injection layer to prepare the OLED, the brightness starts to decrease after the voltage reaches 5 to 7 V. Because the current density of the device increases rapidly, which may be caused by the enhancement of hole injection ability, but electron injection level is not increased, non-radiative recombination in the OLED increases, and the brightness of the OLED decreases.

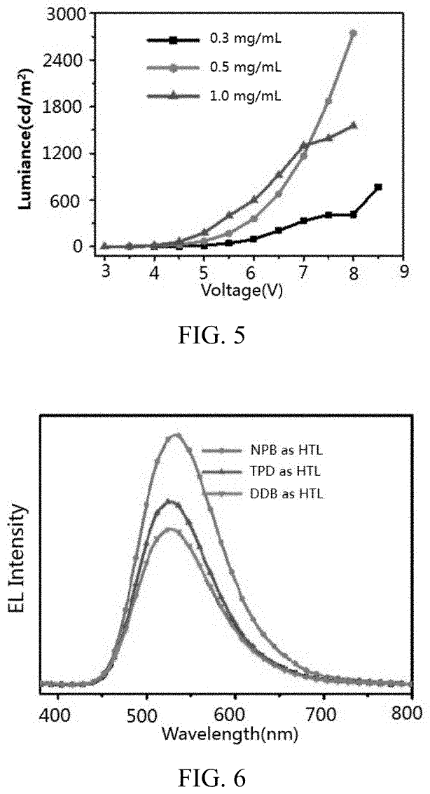

As shown in FIG. 6. FIG. 6 is an electroluminescence spectrum diagram of an OLED using 0.5 mg/mL of graphene oxide as a hole injection layer and three different materials as a hole transport layer. The abscissa is wavelength (in nm) and the ordinate is intensity (in absorbance unit, abbreviated as au). It can be seen from FIG. 6 that the light-emitting layer of this OLED is Alq₃. The graphene oxide solution having a concentration of 0.5 mg/ml is used as a hole injection layer. In the case that other functional layers are unchanged, hole injection ability of different materials of the hole transport layers are different. Charge transport performances of the hole transport layers are: NPB>TPD>DDB.

In summary, in combination with the experimental results of FIGS. 4-6, it can be concluded that the OLED B₂ has the best luminous efficiency, in which the hole injection layer of is prepared with 0.5 mg/ml graphene oxide solution and the hole transporting layer is prepared with the material of N,N′-diphenyl-N,N′-bis(3-tolyl)-1,1′-biphenyl-4,4′-diamine (NPB).

The OLEDs and manufacturing methods provided in the embodiments of the present disclosure comprehensively compare the effects of the graphene oxide solution concentrations and the material choices of the hole transport layer on the light-emitting efficiency of the OLED in the nine embodiments, which is beneficial to the increase of luminous efficiency of the OLED.

The manufacturing method of the graphene oxide film, the OLED, and the manufacturing method thereof provided by the present disclosure employ different concentrations of the graphene oxide solution as hole injection layers and employ specific types of hole transport layers, which are beneficial to the injection and transport of holes and further increase luminous efficiency of OLED.

It can be understood that one of ordinarily skill in the art can carry out changes and modifications to the described embodiment according to technical solutions and technical concepts of the present application, and all such changes and modifications are considered encompassed in the scope of protection defined by the claims of the present application.

1. A manufacturing method of a graphene oxide film, comprising:
a step S10 of providing a graphene oxide aqueous solution in an initial concentration which is a specific concentration and dispersing the initial concentration to a first concentration by an ultraviolet reduction process to prepare a first graphene oxide solution;
a step S20 of putting the first graphene oxide solution into an ultrasonic cleaning apparatus and subjecting the first graphene oxide solution to a shaking water bath in the ultrasonic cleaning apparatus at a first temperature; and
a step S30 of coating the first graphene oxide solution after being subjected to the shaking water bath to form a graphene oxide film by a spin-coating process.

2. The manufacturing method of the graphene oxide film according to claim 1, wherein in the step S10, the first concentration is 0.06-0.2 times as much as the initial concentration.

3. The manufacturing method of the graphene oxide film according to claim 1, wherein in the step S20, the first temperature ranges from 20 to 40° C. and duration of subjecting the first graphene oxide solution to the shaking water bath ranges from 2 to 6 hours.

4. An organic light-emitting diode (OLED), comprising: a substrate, an anode, a hole injection layer, a hole transport layer, a light-emitting layer, an electron transport layer, an electron injection layer, and a cathode stacked in sequence, wherein the hole injection layer is a graphene oxide layer, and the hole transport layer is any one of N,N′-diphenyl-N,N′-bis(3-tolyl)-1,1′-biphenyl-4,4′-diamine, 1,4-bis(diphenylamino) biphenyl, or N,N′-diphenyl-N,N′-bis(1-naphthyl)-1,1′-biphenyl-4,4′-diamine.

5. The OLED according to claim 4, wherein a concentration of a graphene oxide solution used in the graphene oxide layer ranges from 0.3 to 1 mg/ml.

6. A manufacturing method of an organic light-emitting diode (OLED), comprising:
a step S10 of forming an anode on a cleaned substrate by a magnetron sputtering process to obtain an anode substrate;
a step S20 of adjusting a concentration of a graphene oxide solution by an ultraviolet reduction process, and then coating the graphene oxide solution on the anode substrate by a spin coating process, and performing a drying treatment to form a hole injection layer; and
a step S30 of depositing a hole transport layer, a light-emitting layer, an electron transport layer, an electron injection layer, and a cathode on the hole injection layer in sequence by evaporation processes.

7. The manufacturing method of the OLED according to claim 6, wherein the S20 further comprises:
a step S201 of providing a graphene oxide aqueous solution in an initial concentration which is a specific concentration and adjusting the concentration of the graphene oxide solution by the ultraviolet reduction process to prepare a first graphene oxide solution; and
a step S202 of subjecting the first graphene oxide solution to a shaking water bath via an ultrasonic cleaning instrument for 2-6 hours, wherein an ultrasonic process is controlled at 20-40° C., and then coating the first graphene oxide solution on the anode substrate, and performing the drying treatment to form the hole injection layer.

8. The manufacturing method of the OLED according to claim 7, wherein in the step S201, the first concentration is 0.06 to 0.2 times as much as the initial concentration.

9. The manufacturing method of the OLED according to claim 6, wherein in the step S30, an evaporation rate of the light-emitting layer is between 1-4 Å/s, an evaporation rate of the electron injection layer is between 0.1-0.3 Å/s, and an evaporation rate of the cathode is between 1-5 Å/s.

10. The manufacturing method of the OLED according to claim 6, wherein in the step S30, material of the light-emitting layer is tris(8-hydroxyquinoline) aluminum, material of the electron injection layer is LiF, and material of the cathode is Al.
